(19) United States
(12) Patent Application Publication
(10) Pub. No.: US 2010/0089310 A1
(43) Pub. Date: Apr. 15, 2010

(54) DEVICE AND METHOD FOR PRODUCING SELF-SUSTAINED PLATES OF SILICON OR OTHER CRYSTALLINE MATERIALS

(75) Inventors: Roland Einhaus, Bourgoin Jallieu (FR); Francois Lissalde, Seyssins (FR); Yves Delannoy, Crolles (FR)

Correspondence Address: OLIFF & BERRIDGE, PLC, P.O. BOX 320850, ALEXANDRIA, VA, 22320-4850, US

(73) Assignees: Apollon Solar, Paris (FR); Cyberstar, Echirolles (FR); Centre National De La Recherche Scientifique, Paris (FR); Institut Polytechnique De Grenoble, Grenoble (FR)

(21) Appl. No.: 12/449,802

(22) PCT Filed: Mar. 7, 2008
(86) PCT No.: PCT/FR2008/000304

§ 371 Date: Aug. 27, 2009

(30) Foreign Application Priority Data
Mar. 8, 2007 (FR) 0701701

(51) Int. Cl. C30B 11/00

(52) U.S. Cl. 117/73; 117/206

(57) ABSTRACT

The device for producing a sheet of crystalline material by directional solidification of a material in liquid phase composed of a crucible provided with a bottom, side walls and at least one horizontal outlet slot arranged on a bottom part of a side wall. On its external surface in immediate proximity to the slot, the crucible presents electromagnetic means for creating magnetic repulsion forces on the material in liquid phase, at least at the level of the slot. An alternating current with a frequency comprised between 10 kHz and 300 kHz flows through the electromagnetic means. To foster stirring of the material in liquid phase, a low frequency can be used in addition to the above frequencies.

### BACKGROUND OF THE INVENTION

The invention relates to a device for producing a sheet of crystalline material by directional solidification of a material in liquid phase in a crucible equipped with a bottom, side walls and at least one sheet outlet slot, said slot being horizontal and located in the bottom in a bottom part of a side wall.

### STATE OF THE ART

The direct production of sheets of crystalline material by directional solidification of the melted raw material by means of a crucible provided with a slot enables ribbons to be obtained without, after crystallization of an ingot, requiring additional steps like cropping the ingot, slicing the cropped ingot into bricks and cutting the bricks into wafers by slicing. However, to be integrated in photovoltaic cells, the sheets have to present grain boundaries perpendicular to the P/N junctions used and therefore perpendicular to the surface of the sheet.

The major difficulty met with at present with this type of device consists in controlling the vertical thermal gradient in the solidification zone inside the crucible. A device has been proposed in International Patent application PCT/FR2006/002349 (filed on 19 Oct. 2006) in which the solidification interface between the solid phase and liquid phase is located at the level of the lateral slot of the crucible. This device is however difficult to implement and presents certain drawbacks. Solidification inside the crucible is in fact limited to a small surface. In addition, the stirring of the liquid phase is not sufficient for the impurities to have the possibility of migrating into the bath. They can then be present in solid phase with the advance of the solidification front. These impurities are then detrimental to the photovoltaic cells to be integrated.

The articles by Hide et al (“Cast Ribbon for Low Cost Solar Cells” 0160-8371/88/0000-1400, 1988 IEEE 26 Sep. 1988) and by Suzuki et al (“Growth of Polycrystalline Silicon Sheet by Hoxan Cast Ribbon Process” Journal of Crystal Growth, Elsevier, vol 104, no 1, 1 Jul. 1990) present another method of directional solidification by means of an extrusion channel. The silicon is melted inside a crucible and transferred under pressure through a slot located in the centre of the bottom of the crucible. The thimble and elbowed mould attached underneath the crucible then form a narrow elongated channel in the final section. In this final portion, an imposed vertical thermal gradient results in the vertical directional solidification of the whole of the material. The latter is then not able to reject the impurities present in liquid phase out of the solid phase due to the size of the extrusion channel.

### OBJECT OF THE INVENTION

The object of the invention is to remedy these shortcomings and in particular to provide a device and method for producing sheets of crystalline material by directional solidification that is easy to implement and presents a greater rejection of impurities in liquid phase.

This object is achieved by the fact that, on its external surface in immediate proximity to the sheet outlet slot, the crucible presents electromagnetic means for creating magnetic repulsion forces on the material in liquid phase, at least at the level of the sheet outlet slot, by an alternating current with a frequency comprised between 10 kHz and 300 kHz flowing through said electromagnetic means.

### BRIEF DESCRIPTION OF THE DRAWINGS

Other advantages and features will become more clearly apparent from the following description of particular embodiments of the invention given for non-restrictive example purposes only and represented in the appended drawings, in which:

FIG. 1 represents a schematic cross-sectional view of a particular embodiment of the device according to the invention.

FIG. 2 represents a front view of the slot of the device according to FIG. 1.

FIG. 3 represents a schematic cross-sectional view of another particular embodiment of the device according to the invention.

FIG. 4 represents an enlargement of FIG. 3, centred on the slot and the electromagnetic means for creating magnetic forces.

### DESCRIPTION OF A PREFERRED EMBODIMENT OF THE INVENTION

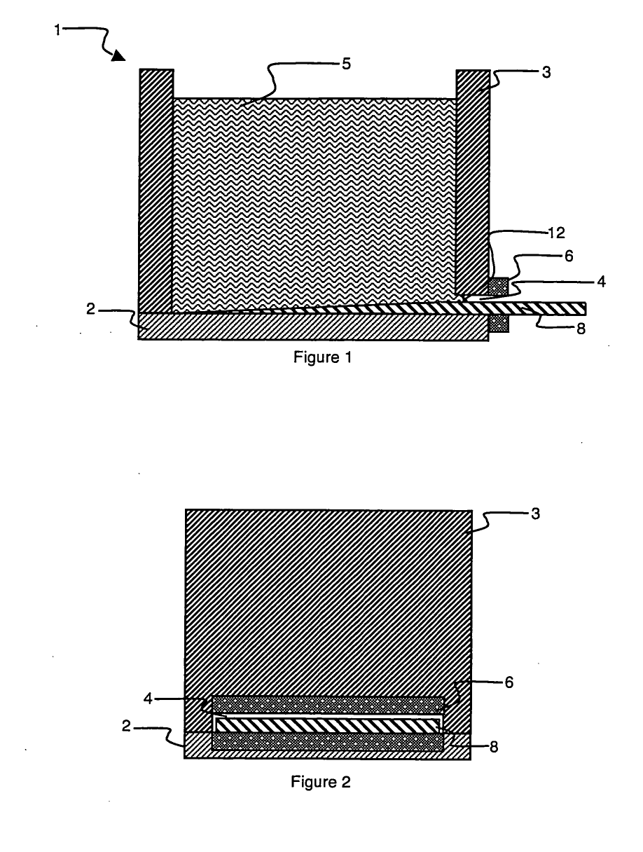

As in Patent application PCT/FR2006/002349, the device represented in FIGS. 1 and 2 comprises a crucible 1 having a bottom 2 and side walls 3. Crucible 1 comprises a lateral outlet slot 4 arranged horizontally at the bottom part of the right-hand side wall 3 in FIG. 1. Crucible 1 is partially filled with a material in liquid phase 5. The outlet slot 4 is in communication with the atmosphere 7 surrounding crucible 1, generally composed by a neutral gas such as argon. A sheet 8 of crystalline material obtained by directional solidification of the material inside crucible 1 is drawn though slot 4.

The crystalline material is for example silicon, germanium, gallium arsenide or others. Conventionally, the thermal gradient inside crucible 1 is vertical, the temperature decreasing from the top of crucible 1 to the bottom 2 thereof. Solidification of the material inside crucible 1 thereby causes the formation of grain boundaries perpendicular to sheet 8 of material in solid phase. This configuration is advantageous for the use in photovoltaic devices.

Directional solidification of the material preferably takes place at the level of the bottom 2 of crucible 1, and the material in solid phase forming sheet 8 is removed from the bath via outlet slot 4 as it solidifies by any suitable gripping means not represented in FIG. 1.

The heat regulation within crucible 1 is performed by any known means to keep the thermal gradient inside crucible 1 stable and vertical.

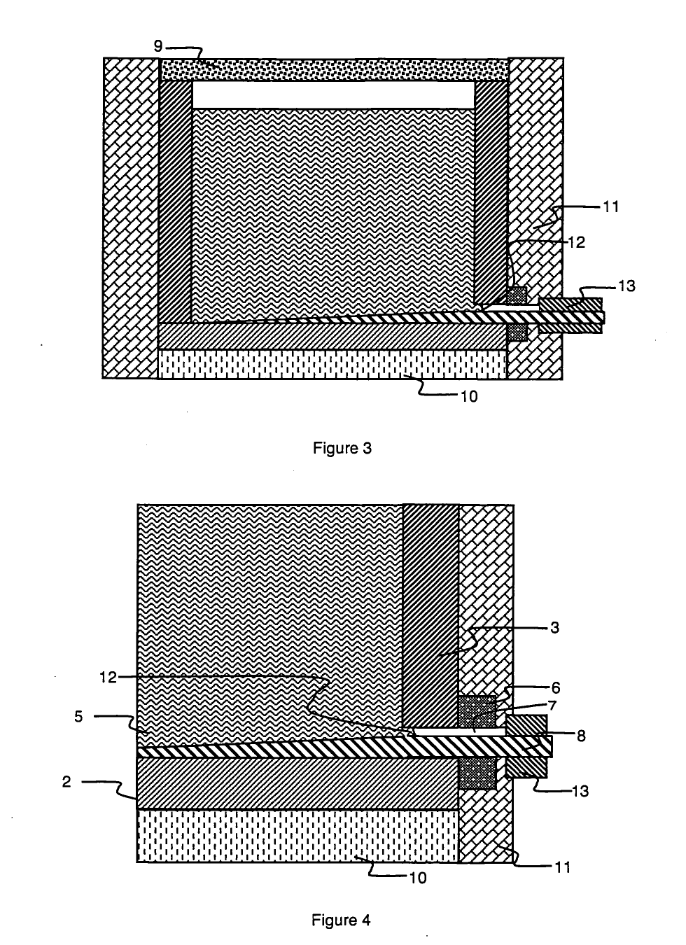

As illustrated in FIG. 3, crucible 1 can advantageously be coupled with a heating system 9 preferably located above the crucible 1 and with a heat extraction system 10 preferably located underneath crucible 1 so as to keep the thermal gradient substantially vertical. The thermal gradient inside crucible 1 is substantially perpendicular to the solidification interface. Heat extraction system 10 regulates the heat flow extracted under the material during solidification and the distribution of the heat flow according to the distance from slot 4. The heat extraction system 10 is for example a heat transfer by radiation through a transparent bottom 2 of crucible 1.

As illustrated in FIG. 3, the side walls 3 of crucible 1 are advantageously coupled to a thermal insulator 11. This thermal insulator 11 is preferably placed outside crucible 1 over the whole surface delineated by the side walls 3. In this way the lateral loss through the side walls 3 is suppressed and the thermal gradient is kept substantially vertical.

The solidification interface of the material, substantially perpendicular to the thermal gradient, is situated in the bottom part of crucible 1, preferably close to bottom 2 of crucible 1. This position is adjusted by means of the thermal gradient inside crucible 1. The thickness of sheet 8 obtained in this way is essentially defined by the heat fluxes within crucible 1 and by the withdrawal rate of sheet 8 out of the crucible 1. The withdrawal rate of sheet 8 is preferably in the 0.5-10 metres/minute range.

The height of slot 4 is chosen to be larger than the thickness of sheet 8 so as to prevent any mechanical clogging and parasistic solidification when sheet 8 is withdrawn via slot 4.

The device further comprises at least one inductor 6 outside crucible 1, against side wall 3, in immediate proximity to the outlet slot 4. The inductor 6 presents a preferred embodiment of electromagnetic means for creating magnetic forces 6. An alternating current having a frequency comprised between 10 kHz and 300 kHz and an intensity preferably comprised between 100 A and 3000 A flows through the inductor 6. The inductor 6 thereby creates magnetic repulsion forces on the material in liquid phase 5.

The inductor 6 can be located above or below the slot 4. In the particular embodiment of FIG. 1, two inductors 6 are disposed on each side of slot 4.

As illustrated in greater detail in FIG. 4, the interface between the material in liquid phase 5 and the atmosphere 7 is in the shape of a meniscus 12. As the magnetic repulsion forces produced by the inductor 6 only have an effect on the material in liquid phase 5, the inductor 6 enables the position of the meniscus 12 to be controlled. The latter is preferably located inside the slot 4 so as to prevent any material in liquid phase 5 from leaking via slot 4 without disturbing the crystallization of the material in liquid phase 5 inside crucible 1. The magnetic repulsion forces imposed by inductor 6 are adjusted so that repulsion of the material in liquid phase 5 takes place at the level of outlet slot 4, above the sheet 8. Repulsion forces also act between the edges of sheet 8 and each lateral end. The material in the liquid phase 5 is thereby kept inside crucible 1. The amplitude of the current in inductor 6 is determined according to the hydrostatic pressure of the material in liquid phase 5 in crucible 1 and to the distance between inductor 6 and meniscus 12. The cross-section of the inductor 6 is chosen such as to concentrate the repulsion forces optimally on the meniscus 12.

An example of an embodiment of the device implements an inductor 6 concentrating the currents at about 5 mm from the meniscus 12. This inductor enables a height of 5 cm of silicon to be kept in the crucible when a current of 900 A flows through the inductor at a frequency of 30 Khz. Slot 4 presents a width of 75 mm and a height of 3 mm.

The inductor 6 further causes a stirring effect of the material in liquid phase 5 near slot 4. It creates recirculation loops of the material in liquid phase 5 which draw off the impurities originating from the solidification interface in the whole of the material in liquid phase 5. Accumulation of the impurities close to the solid phase is thereby reduced in comparison with the prior art due to the presence of a more extensive solidification front. The stirring effect is enhanced by the use of a current in the inductor in the low frequency range, for example about 50 Hz. The device therefore preferably comprises means for combining a frequency suitable for stirring the material in liquid phase 5 with the frequency range comprised between 10 kHz and 300 Khz.

In an alternative embodiment, two inductors 6 are provided respectively having currents of different frequencies flowing through them. A first inductor is then supplied by a current having a frequency such as to ensure stirring of the material in liquid phase 5, preferably in the low frequency range, around 50 Hz. The other inductor has a current with a frequency comprised between 10 kHz and 300 kHz flowing through it to ensure the repulsion of the material in liquid phase 5. This simultaneous action can also be achieved by a single inductor, for example by frequency modulation, amplitude over-modulation, etc.

Outside the outlet from slot 4, the sheet 8 of crystalline material is constituted exclusively of the solid phase. The material in liquid phase 5 is in fact pushed back inside the crucible 1 by the inductor 6. The sheet 8 is then self-supported as soon as it exits the crucible.

It is preferably to bring a crystallisation seed in contact with the material in liquid phase 5 when the solidification begins. The crystallization seed is preferably brought into contact with meniscus 12 to enable crystallization under predetermined orientations.

Nucleation/germination centres, for example formed by localized heat sinks, can be added at the level of the interface between bottom 2 of the crucible 1 and the material in liquid phase 5 to facilitate the beginning of crystallization.

In the particular embodiment represented in FIG. 3, a processing device 13, in particular a thermal processing device, is coupled to the crucible 1 on exit from slot 4. This device enables a predefined profile of the cooling kinetics of sheet 8 to be monitored. This profile allows the mechanical stresses and the density of crystalline defects to be reduced. Device 13 can moreover serve the purpose of preheating the seed crystal used for beginning solidification.

1.-9. (canceled)

10. A device for producing a sheet of crystalline material, said device comprising a crucible comprising:
a bottom,
side walls,
at least one outlet slot for said sheet, said slot being horizontal and formed in a bottom part of a side wall of the crucible,
said crucible being configured to produce said sheet of crystalline material by directional solidification from a material in liquid phase within the crucible,
device wherein electromagnetic means are located on the external surface of the crucible in immediate proximity to the sheet outlet slot, an alternating current with a frequency comprised between 10 kHz and 300 kHz flowing through said electromagnetic means for creating magnetic repulsion forces on the material in liquid phase, at least at the level of the sheet outlet slot.

11. The device according to claim 10 wherein the electromagnetic means for creating magnetic forces are located above the slot.

12. The device according to claim 10 wherein the electromagnetic means for creating magnetic forces are located below the slot.

13. The device according to claim 10 wherein the electromagnetic means for creating magnetic forces comprise at least one inductor.

14. The device according to claim 10 comprising means for superposing a frequency fostering stirring of the material in liquid phase.

15. The device according to claim 10 wherein the frequency fostering stirring is about 50 Hz.

16. The device according to claim 10 wherein a current having an intensity comprised between 100 A and 3000 A flows through the electromagnetic means for creating magnetic forces.

17. The device according to claim 10 comprising means for producing and maintaining a thermal gradient in the material perpendicularly to the bottom of the crucible.

18. A method for producing a sheet of crystalline material by directional solidification of a material in liquid phase in a crucible of a device according to claim 10 wherein the magnetic repulsion forces are applied on the material in liquid phase, at the level of the slot, for solidification of the material in liquid phase taking place on the bottom of the crucible, to prevent leakage of the material in liquid phase.
